(19) United States
(12) Patent Application Publication
(10) Pub. No.: US 2021/0083661 A1
(43) Pub. Date: Mar. 18, 2021

(54) VARIABLE CAPACITANCE CIRCUIT

(71) Applicants: Kabushiki Kaisha Toshiba, Tokyo (JP); Toshiba Electronic Devices & Storage Corporation, Tokyo (JP)

(72) Inventors: Hironori Nagasawa, Yokohama Kanagawa (JP); Takayuki Teraguchi, Kawasaki Kanagawa (JP)

(73) Assignees: Kabushiki Kaisha Toshiba, Minato-ku, Tokyo (JP); Toshiba Electronic Devices & Storage Corporation, Minato-ku, Tokyo (JP)

(21) Appl. No.: 16/923,399

(22) Filed: Jul. 8, 2020

(30) Foreign Application Priority Data
Sep. 12, 2019 (JP) 2019-166293

(51) Int. Cl. H03K 17/16; H01L 27/06; H01L 27/08

(52) U.S. Cl. CPC H03K 17/161; H01L 27/0805; H01L 27/0629

(57) ABSTRACT

A variable capacitance circuit has a plurality of series circuits connected in parallel. The plurality of series circuits comprise a plurality of switches having different off-capacitances of powers of two with respect to a reference capacitance, and a plurality of capacitors connected in series to the plurality of switches and having different capacitances of powers of two with respect to a reference capacitance.

### CROSS REFERENCE TO RELATED APPLICATIONS

This application is based upon and claims the benefit of priority from the prior Japanese Patent Application No. 2019-166293, filed on Sep. 12, 2019, the entire contents of which are incorporated herein by reference.

### FIELD

Embodiments of the present invention relate to a variable capacitance circuit.

### BACKGROUND

There has been known a variable capacitance circuit capable of switching capacitance in a plurality of steps, which has a plurality of series circuits connected in parallel, each series circuit having a MOS transistor and a capacitor connected in series and each MOS transistor being turned ON or OFF.

It is ideally desirable to switch the capacitance linearly in this type of variable capacitance circuit, but there is a practical problem that the capacitance is switched nonlinearly because the MOS transistor has the off-capacitance.

### BRIEF DESCRIPTION OF THE DRAWINGS

FIG. 1 is a circuit diagram of a variable capacitance circuit according to an embodiment;

FIG. 2 is a circuit diagram of a variable capacitance circuit whose switches are configured as NMOS transistors;

FIG. 3 is an equivalent circuit diagram when one MOS transistor of FIG. 2 is turned on;

FIG. 4 is an equivalent circuit diagram when two MOS transistors of FIG. 2 are turned on;

FIG. 5 is an equivalent circuit diagram when all the MOS transistors in FIG. 2 are turned on;

FIG. 6 is a diagram illustrating an example in which the number of MOS transistors connected in parallel is adjusted to have different off-capacitances that are powers of two; and

FIG. 7 is a diagram illustrating an example in which one switch is configured using a plurality of cascode-connected MOS transistors.

### DETAILED DESCRIPTION

According to one embodiment, a variable capacitance circuit has a plurality of series circuits connected in parallel. The plurality of series circuits comprise a plurality of switches having different off-capacitances that are powers of two times a reference capacitance, and a plurality of capacitors connected in series to the plurality of switches and having different capacitances that are powers of two times a reference capacitance.

Hereinafter, embodiments of a variable capacitance circuit will be described with reference to the drawings. Hereinafter, the main components of the variable capacitance circuit will be mainly described, but the variable capacitance circuit may have components and functions that are not illustrated or described. The following description does not exclude the components and functions that are not illustrated or described.

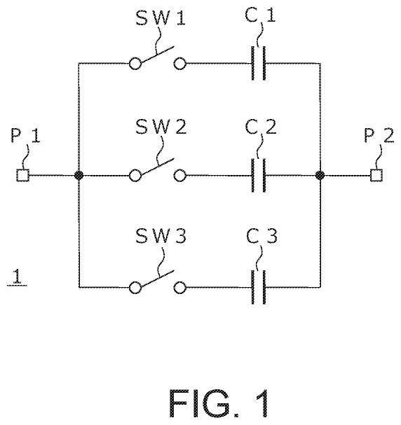

FIG. 1 is a circuit diagram of a variable capacitance circuit 1 according to an embodiment. The variable capacitance circuit 1 of FIG. 1 is characterized in that the capacitance can be switched linearly based on a capacitance switching signal of a plurality of bits.

The variable capacitance circuit 1 of FIG. 1 is configured by connecting a plurality of series circuits in parallel between nodes P1 and P2. Although FIG. 1 illustrates an example in which three series circuits are connected in parallel, the number of series circuits connected in parallel is not limited to this number as long as the number is two or more.

The plurality of series circuits includes switches SW1, SW2, and SW3 that are turned on or off according to a capacitance switching signal, and capacitors C1, C2, and C3 connected in series to the switches SW1, SW2, and SW3, respectively. In the specification, it is assumed that the capacitors C1, C2, and C3 have capacitances C1, C2, and C3, respectively.

When the off-capacitances of the switches SW1, SW2, and SW3 can be ignored, the variable capacitance circuit 1 in FIG. 1 can turn on and off the switches SW1, SW2, and SW3 individually to obtain seven equivalent capacitances in the following (A) to (F).

(A) If only SW1 is turned on, the equivalent capacitance is C1

(B) If only SW2 is turned on, the equivalent capacitance is C2.

(C) If both SW2 and SW1 are turned on, the equivalent capacitance is C2+C1

(D) If only SW3 is turned on, the equivalent capacitance is C3

(E) If both SW3 and SW1 are turned on, the equivalent capacitance is C3+C1

(F) If both SW3 and SW2 are turned on, the equivalent capacitance is C3+C2.

(G) If all SW3, SW2 and SW1 are all turned on, the equivalent capacitance is C3+C2+C1

In practice, the plurality of switches in the plurality of series circuits have different off-capacitances that are powers of two times a reference capacitance. For example, when an off-capacitance of a switch having the smallest off-capacitance among a plurality of switches is C0 and the total number of switches is n, off-capacitances of the other switches is C0×2, C0×4, . . . , and C0×2ⁿ⁻¹. For example, in the example of FIG. 1, the off-capacitances of the switches SW1, SW2, and SW3 are C0, C0×2, and C0×4, respectively.

In addition, the plurality of capacitors of the plurality of series circuits have different off-capacitances that are powers of two times a reference capacitance. For example, when a capacitance of a capacitor having the smallest capacitance among a plurality of capacitors is C1, capacitances of the other capacitors are C1×2, C1×4, . . . , and C1×2ⁿ⁻¹. For example, in the example of FIG. 1, the capacitances of the capacitors C1, C2, and C3 are C1, C1×2, and C1×4, respectively.

The exponent of power in this specification is a natural number to switch the off-capacitances of the plurality of switches and the capacitances of the plurality of capacitors linearly, and is typically a natural number that changes by one. The natural number is an integer of one or more. A specific capacitance value of the reference capacitance is arbitrary.

Among the plurality of series circuits, a series circuit having a switch with the smallest off-capacitance has a capacitor with the smallest capacitance, and a series circuit having a switch with the m-th off-capacitance (m is an integer of two or more) from the smallest capacitance has a capacitor with the m-th capacitance from the smallest capacitance.

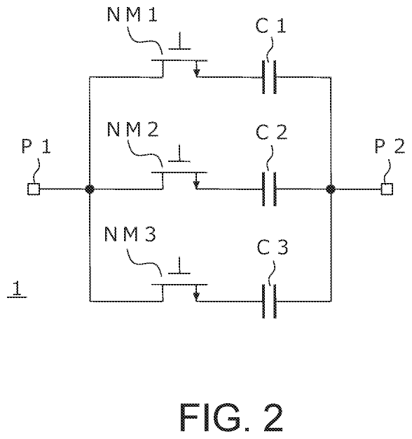

Each switch comprises, for example, a MOS semiconductor element. As a more specific example, the switch is an N-type MOS transistor. A bit corresponding to the capacitance switching signal is input to a gate of each MOS transistor. When the variable capacitance circuit 1 has three series circuits, the capacitance switching signal is a 3-bit signal. FIG. 2 illustrates an example in which three N-type MOS transistors are used as three switch circuits. First, an equivalent resistance and an equivalent capacitance of the variable capacitance circuit 1 according to the embodiment will be described. Hereinafter, it is assumed that equivalent resistances in the above-described cases (A) to (G) in the variable capacitance circuit 1 in FIG. 1 are Req1 to Req7, and the equivalent capacitances are Ceq1 to Ceq7.

(A) The case where only MOS transistor NM1 is turned on

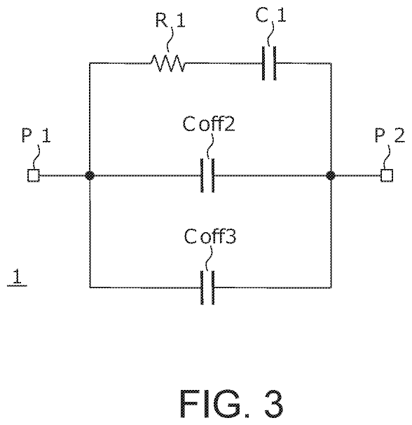

FIG. 3 is an equivalent circuit diagram in the case where only the MOS transistor NM1 of FIG. 2 is turned on. It is assumed that an on-resistance of the MOS transistor NM1 is R1, a combined capacitance of an off-capacitance of the MOS transistor NM2 and a capacitance of the capacitor C2 is Coff2, and a combined capacitance of an off-capacitance of the MOS transistor NM3 and a capacitance of the capacitor C3 is Coff3.

The combined capacitances Coff2 and Coff3 are expressed by the following Formulas (1) and (2).

1/Coff2=1/(off-capacitance of NM2)+1/C2 (1)

1/Coff3=1/(off-capacitance of NM3)+1/C3 (2)

An admittance Y1 based on the series connection of an on-resistance R1 of the MOS transistor NM1 and the capacitor C1 is expressed by the following Formula (3). Here, j is an imaginary unit, and w is an angular frequency.

$${Y}_{1} = \frac{ω {C}_{1}}{ω {C}_{1} {R}_{1} - j} = \frac{{ω}^{2} {C}_{1}^{2} {R}_{1} + j ω {C}_{1}}{{ω}^{2} {C}_{1}^{2} {R}_{1}^{2} + 1} \qquad ( 3 )$$

From Formula (3), a total admittance Y0 of the variable capacitance circuit 1 in FIG. 3 is expressed by Formula (4).

$${Y}_{0} = {Y}_{1} + {Y}_{2} + {Y}_{3} = \frac{{ω}^{2} {C}_{1}^{2} {R}_{1} + j ω {C}_{1}}{{ω}^{2} {C}_{1}^{2} {R}_{1}^{2} + 1} + j ω ( {C}_{off 2} + {C}_{off 3} ) = \frac{{ω}^{2} {C}_{1}^{2} {R}_{1}}{{ω}^{2} {C}_{1}^{2} {R}_{1}^{2} + 1} + j ω ( \frac{{C}_{1}}{{ω}^{2} {C}_{1}^{2} {R}_{1}^{2} + 1} + {C}_{off 2} + {C}_{off 3} ) \qquad ( 4 )$$

From Formula (4), the equivalent resistance Req1 is expressed by Formula (5).

$${R}_{eq 1} = 1 \text{/} Re ( {Y}_{0} ) = {R}_{1} + \frac{1}{ω {C}_{1} {R}_{1}} \approx {R}_{1} \qquad ( 5 )$$

In addition, the equivalent capacitance Ceq1 is expressed by Formula (6).

$${C}_{eq 1} = \frac{1}{ω} Im ( {Y}_{0} ) = {C}_{1} + {C}_{off 2} + {C}_{off 3} \qquad ( 6 )$$

In Formula (5) and Formula (6), Re( ) and Im( ) mean to take the real part and the imaginary part in ( ), respectively.

The equivalent resistances and equivalent capacitances in the case (B) where only the MOS transistor NM2 is turned on and in the case (C) where the MOS transistor NM3 is turned on are expressed by formulas obtained by substituting suffixes in Formulas (2) to (4).

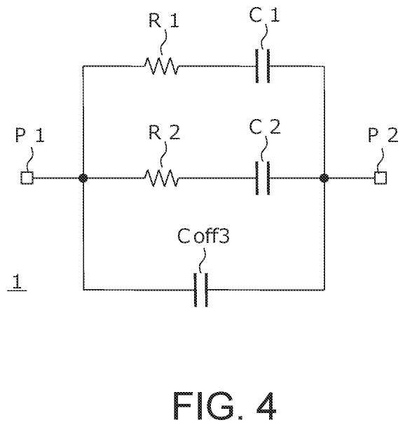

FIG. 4 is an equivalent circuit diagram in the case (C) where both the MOS transistors NM1 and NM2 are turned on. An on-resistance of the MOS transistor NM2 is R2, and other symbols are the same as those in FIG. 3.

A total admittance Y0 of the equivalent circuit of FIG. 4 is expressed by Formula (7).

$${Y}_{0} = {Y}_{1} + {Y}_{2} + {Y}_{3} = \frac{{ω}^{2} {C}_{1}^{2} {R}_{1} + j ω {C}_{1}}{{ω}^{2} {C}_{1}^{2} {R}_{1}^{2} + 1} + \frac{{ω}^{2} {C}_{2}^{2} {R}_{2} + j ω {C}_{2}}{{ω}^{2} {C}_{2}^{2} {R}_{2}^{2} + 1} + j ω {C}_{off 3} = ( \frac{{ω}^{2} {C}_{1}^{2} {R}_{1}}{{ω}^{2} {C}_{1}^{2} {R}_{1}^{2} + 1} + \frac{{ω}^{2} {C}_{2}^{2} {R}_{2}}{{ω}^{2} {C}_{2}^{2} {R}_{2}^{2} + 1} ) + j ω ( \frac{{C}_{1}}{{ω}^{2} {C}_{1}^{2} {R}_{1}^{2} + 1} + \frac{{C}_{2}}{{ω}^{2} {C}_{2}^{2} {R}_{2}^{2} + 1} + {C}_{off 3} ) \qquad ( 7 )$$

From Formula (7), the equivalent resistance Req3 is expressed by the following Formula (8).

$${R}_{eq 3} = 1 \text{/} Re ( {Y}_{0} ) \approx \frac{1}{1 \text{/} {R}_{1} + 1 \text{/} {R}_{2}} \qquad ( 8 )$$

From Formula (7), the equivalent capacitance Ceq3 is expressed by the following Formula (9).

$${C}_{e q 3} = \frac{1}{ω} Im ( {Y}_{0} ) = {C}_{1} + {C}_{2} + {C}_{off 3} \qquad ( 9 )$$

The equivalent resistances and equivalent capacitances in the case (F) where both the MOS transistors NM2 and NM3 are turned on and the case (E) where both the MOS transistors NM3 and NM1 are turned on are expressed by formulas obtained by substituting suffixes in Formulas (7) to (9).

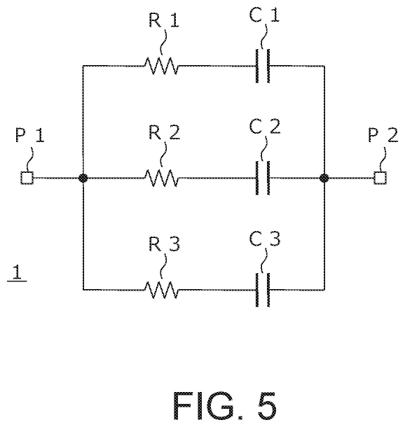

FIG. 5 illustrates an equivalent circuit diagram in the case (G) where the MOS transistors NM1, NM2, and NM3 are all turned on. A total admittance Y0 is expressed by Formula (10).

$${Y}_{0} = {Y}_{1} + {Y}_{2} + {Y}_{3} = \frac{{ω}^{2} {C}_{1}^{2} {R}_{1} + j ω {C}_{1}}{{ω}^{2} {C}_{1}^{2} {R}_{1}^{2} + 1} + \frac{{ω}^{2} {C}_{2}^{2} {R}_{2} + j ω {C}_{2}}{{ω}^{2} {C}_{2}^{2} {R}_{2}^{2} + 1} + \frac{{ω}^{2} {C}_{3}^{2} {R}_{3} + j ω {C}_{3}}{{ω}^{2} {C}_{3}^{2} {R}_{3}^{2} + 1} = ( \frac{{ω}^{2} {C}_{1}^{2} {R}_{1}}{{ω}^{2} {C}_{1}^{2} {R}_{1}^{2} + 1} + \frac{{ω}^{2} {C}_{2}^{2} {R}_{2}}{{ω}^{2} {C}_{2}^{2} {R}_{2}^{2} + 1} + \frac{{ω}^{2} {C}_{3}^{2} {R}_{3}}{{ω}^{2} {C}_{3}^{2} {R}_{3}^{2} + 1} ) + j ω ( \frac{{C}_{1}}{{ω}^{2} {C}_{1}^{2} {R}_{1}^{2} + 1} + \frac{{C}_{2}}{{ω}^{2} {C}_{2}^{2} {R}_{2}^{2} + 1} + \frac{{C}_{3}}{{ω}^{2} {C}_{3}^{2} {R}_{3}^{2} + 1} ) \qquad ( 10 )$$

From Formula (10), the equivalent resistance Req7 is expressed by the following Formula (11).

$${R}_{eq 7} = 1 \text{/} Re ( {Y}_{0} ) = \frac{1}{1 \text{/} {R}_{1} + 1 \text{/} {R}_{2} + 1 \text{/} {R}_{3}} \qquad ( 11 )$$

From Formula (10), the equivalent capacitance Ceq is expressed by the following Formula (12).

$${C}_{eq 7} = \frac{1}{ω} Im ( {Y}_{0} ) = {C}_{1} + {C}_{2} + {C}_{3} \qquad ( 12 )$$

To sum up the above, the equivalent resistances Req1 to Req7 of (A) to (G) described above in the variable capacitance circuit 1 of FIG. 1 are expressed by the following Formulas (13) to (19), and the equivalent capacitances Ceq1 to Ceq7 are expressed by the following Formulas (20) to (26).

Req1=R1 (13)

Req2=R2 (14)

Req3=1/(1/R1+1/R2) (15)

Req4=R3 (16)

Req5=1/(1/R1+1/R3) (17)

Req5=1/(1/R2+1/R3) (18)

Req7=1/(1/R1+1/R2+1/R3) (19)

Ceq1=C1+Coff2+Coff3 (20)

Ceq2=C2+Coff1+Coff3 (21)

Ceq3=C1+C2+Coff3 (22)

Ceq4=C3+Coff1+Coff2 (23)

Ceq5=C1+C3+Coff2 (24)

Ceq6=C2+C3+Coff1 (25)

Ceq7=C1+C2+C3 (26)

Next, each capacitance deviation between the respective steps from the equivalent capacitance Ceq1 to Ceq7 is defined as the following Formulas (27) to (32).

ΔC(2,1)=Ceq2−Ceq1 (27)

ΔC(3,2)=Ceq3−Ceq2 (28)

ΔC(4,3)=Ceq4−Ceq3 (29)

ΔC(5,4)=Ceq5−Ceq4 (30)

ΔC(6,5)=Ceq6−Ceq5 (31)

ΔC(7,6)=Ceq7−Ceq6 (32)

Formulas (27) to (32) are expressed by the following Formulas (33) to (38) based on Formulas (20) to (26) described above.

ΔC(2,1)=(C2−C1)+(Coff1−Coff2) (33)

ΔC(3,2)=C1−Coff1 (34)

ΔC(4,3)=(C3−C2−C1)+Coff1+Coff2−Coff3 (35)

ΔC(5,4)=C1−Coff1 (36)

ΔC(6,5)=(C2−C1)+(Coff1−Coff2) (37)

ΔC(7,6)=C1−Coff1 (38)

When C2=2×C1 and C3=4×C1 are established and Coff2=b1×Coff1 and Coff3=b2×Coff1 are established in the above (A) to (G), Formulas (33) to (38) described above are expressed by the following Formulas (39) to (44).

ΔC(2,1)=C1+(1−b1)·Coff1 (39)

ΔC(3,2)=C1−Coff1 (40)

ΔC(4,3)=C1+(1+b1−b2)·Coff1 (41)

ΔC(5,4)=C1−Coff1 (42)

ΔC(6,5)=C1+(1−b1)·Coff1 (43)

ΔC(7,6)=C1−Coff1 (44)

Here, if b1=2 and b2=4, 1−b1=−1 and 1+b1−b2=−1, and the following Formula (45) is always established.

Here, X is an integer of one to seven.

ΔC(X+1,X)=C1−Coff1 (45)

That is, all the capacitance deviations between the respective steps are equally C1−Coff1. In other words, the linear relationship is established between the capacitance and the variable X.

Here, the combined capacitances Coff1, Coff2, and Coff3 are not equal to the off-capacitances of the MOS transistors NM1, NM2, and NM3, respectively, but have the relationship as in the following Formulas (46) to (48).

$$\begin{matrix} 1 \text{/} C off 1 = 1 \text{/} ( off \text{-} capacitance of NM 1 ) + 1 \text{/} C 1 & ( 46 ) \\ 1 \text{/} C off 2 = 1 \text{/} ( off \text{-} capacitance of NM 2 ) + 1 \text{/} C 2 = 1 \text{/} 2 \text{/} ( off \text{-} capacitance of NM 1 ) + 1 \text{/} 2 \text{/} C 1 = 1 \text{/} 2 Coff 1 & ( 47 ) \\ 1 \text{/} C off 3 = 1 \text{/} ( off \text{-} capacitance of NM 3 ) + 1 \text{/} C 3 = 1 \text{/} 4 \text{/} ( off \text{-} capacitance of NM 1 ) + 1 \text{/} 4 \text{/} C 1 = 1 \text{/} 4 Coff 1 & ( 48 )\end{matrix}$$

From Formulas (46) to (48), the following Formulas (49) and (50) are established.

Coff2=2×Coff1 (49)

Coff3=4×Coff1 (50)

Formulas (49) and (50) can be realized by satisfying the following Formulas (51) and (52).

Gate width of NM2/gate width of NM1=2 (51)

Gate width of NM3/gate width of NM1=4 (52)

Note that Formulas (51) and (52) assume that gate lengths of the MOS transistors NM1 to NM3 are made equal and the gate widths are made differently. Conversely, the MOS transistors NM1 to NM3 whose gates have same widths may be made such that the gate lengths satisfy the same relationship as in Formulas (51) and (52).

In the embodiment, as described above, the plurality of series circuits connected in parallel have different capacitances of the powers of two times the reference capacitance, and MOS transistors in the plurality of series circuits have different off-capacitances of the powers of two times the reference capacitance. As a specific method for making the plurality of MOS transistors to have different off-capacitances of the powers of two times the reference capacitance, the plurality of MOS transistors may have different gate widths that are powers of two times a reference width as illustrated in the Formulas (51) and (52). Alternatively, the plurality of MOS transistors may have different gate lengths that are powers of two times a reference length. A specific value of the reference width for the gate width and a specific value of the reference length for the gate length are arbitrary.

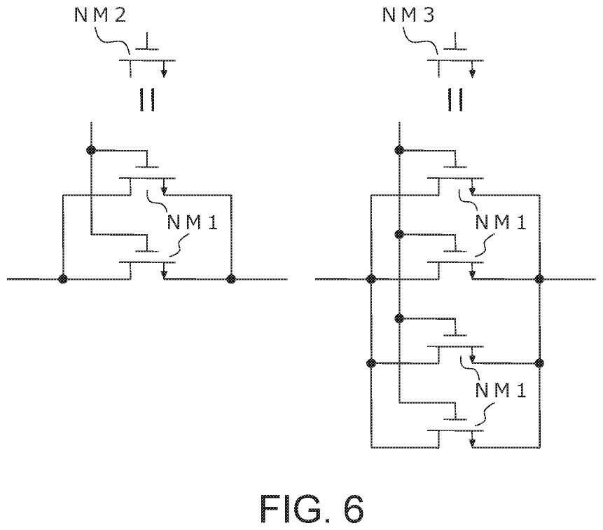

Instead of adjusting the gate width and gate length, the number of MOS transistors connected in parallel may be adjusted to have different off-capacitances that are powers of two times a reference capacitance as illustrated in FIG. 6. In the example of FIG. 6, the MOS transistor NM2 is configured by connecting two MOS transistors NM1 in parallel, and the MOS transistor NM3 is configured by connecting four MOS transistors NM1 in parallel. A gate, a drain, and a source are connected in common to the plurality of MOS transistors NM1 connected in parallel. When the number of MOS transistors NM1 connected in parallel is increased by a power of two times a reference number, the off-capacitance can also be increased by a power of two. A specific numerical value of the reference number is arbitrary.

When the number of MOS transistors connected in parallel is adjusted by the power of two times the reference number as illustrated in FIG. 6, the off-capacitance can be adjusted even when the gate widths and the gate lengths are the same.

Although the variable capacitance circuit 1 in which the three series circuits are connected in parallel has been described above, the variable capacitance circuit 1 in which two series circuits are connected in parallel will be described hereinafter. In this case, a capacitance switching signal to switch on/off of a switch is two bits. In addition, equivalent circuit diagrams are circuits obtained by deleting the combined capacitance Coff3 from FIGS. 3 and 4, and a circuit obtained by deleting the on-resistance R3 and the capacitor C3 from FIG. 5. Accordingly, equivalent capacitances Ceq1, Ceq2, and Ceq3 of the variable capacitance circuit 1 in which the two series circuits are connected in parallel are expressed by the following Formulas (53) to (55).

Ceq1=C1+Coff2 (53)

Ceq2=C2+Coff1 (54)

Ceq3=C1+C2 (55)

Here, when C2=2×C1 and Coff2=2×Coff1 are assumed, Formulas (53) to (55) are expressed by Formulas (56) to (58).

Ceq1=C1+Coff1 (56)

Ceq2=2C1+Coff1 (57)

Ceq3=3C1 (58)

Accordingly, capacitance deviations between the equivalent capacitances are expressed by the following Formulas (59) and (60).

ΔC21=C1−Coff1 (59)

ΔC32=C1−Coff1 (60)

In this manner, the capacitance deviations are equally C1 −Coff1. This can be realized by setting the gate width of NM2/gate width of NM1=2 with the gate lengths of the NMOS transistors NM1 and NM2 being the same or by configuring the MOS transistor NM2 as the parallel connection of the two MOS transistors NM1 as illustrated in FIG. 6. Alternatively, the gate lengths may be adjusted while keeping the gate widths constant.

Next, the variable capacitance circuit 1 in which four series circuits are connected in parallel will be described. In this case, a capacitance switching signal is four bits. It is assumed that capacitances of capacitors are C1, C2, C3, and C4, on-resistances of MOS transistors NM1, NM2, NM3, and NM4 are R1, R2, R3, and R4, and combined capacitances are Coff1, Coff2, Coff3, and Coff4.

If it is set such that C2=2×C1, C3=4×C1, C4=8×C1, Coff2=2×Coff1, Coff3=4×Coff1, and Coff4=8×Coff1, each capacitance deviation between steps is equally C1−Coff1, which is similar to the case where the capacitance switching signal is two bits or three bits.

The variable capacitance circuit 1 in which N(N is an integer of two or more) series circuits are connected in parallel will be examined based on the above findings. In this case, a capacitance switching signal has N bits (N is an integer of two or more), capacitances of N capacitors are C1, C2, . . . , and CN, combined capacitances of the respective capacitors are Coff1, Coff2, . . . , and CoffN.

Here, when the capacitor Ck (k is an arbitrary integer from zero to N−1) is set as in the following Formula (61) and the combined capacitance Coffk is set as in Formula (62), a capacitance deviation between steps can be set to C1−Coff1.

Ck=2^{k}×C1 (61)

Coffk=2^{k}×Coff1 (62)

The above description will be described using a binary system. The equivalent capacitance Ceq can be expressed by the following Formula (63).

Ceq=(sum of capacitance values of switches that are turned on)+(sum of off-capacitances of switches that are turned off) (63)

Formula (63) can be expressed by the following Formula (64).

$${C}_{eq} = {C}_{1} \cdot {\sum }_{k = 0}^{N - 1} {2}^{k} {A}_{k} + {C}_{off 1} \cdot {\sum }_{k = 0}^{N - 1} {2}^{k} {B}_{k} \qquad ( 64 )$$

In Formula (64), the first term on the right side is a sum of capacitance values of switches that are turned on, and the second term on the right side is a sum of combined capacitances of switches that are turned off.

In Formula (64), Ak in the first term on the right side indicates whether a k-th bit of the capacitance switching signal is one or zero, and the switch is turned on when Ak=1 and is turned off when Ak=0. Further, Bk in the second term on the right side is the reverse of Ak, and the switch is turned off when Bk=1 and is turned on when Bk=0. The binary number represented by Bk is a complement of one of the binary number represented by Ak. Thus, the following Formula (65) is established.

$${\sum }_{k = 0}^{N - 1} {2}^{k} {B}_{k} = {\sum }_{k = 0}^{N - 1} {2}^{k} ( 1 - {A}_{k} ) = {\sum }_{k = 0}^{N - 1} {2}^{k} - {\sum }_{k = 0}^{N - 1} {2}^{k} {A}_{k} \qquad ( 65 )$$

Here, if X represents a step, X is obtained by converting the binary number Ak to a decimal number. As a result, X is expressed by Formula (66), and the increment of Formula (64) is C1 when X increases by one.

$$X = {\sum }_{k = 0}^{N - 1} {2}^{k} {A}_{k} \qquad ( 66 )$$

Since the binary number represented by Bk in the second term on the right side of Formula (64) is the complement of one of the binary number represented by Ak, the increase in X by one means that the second term on the rightmost side of Formula (65) increases by one, and the value of Formula (65) decreases by one. Therefore, the second term on the right side of Formula (64) decreases by Coff1 when X increases by one. From the above, when X increases by 1, the equivalent capacitance Ceq increases by C1−Coff1, and the capacitance deviation between steps is equivalent to C1−Coff1.

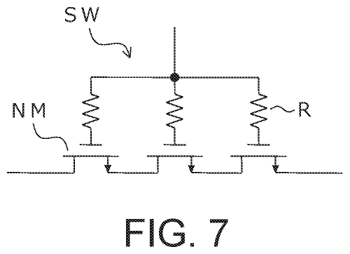

Although the example in which the switch is configured using the MOS transistor is illustrated in FIG. 1 and the like, a single switch SW may be configured using a plurality of cascode-connected MOS transistors NM as illustrated in FIG. 7 in order to improve a breakdown voltage of the switch. The switch SW in FIG. 7 includes three cascode-connected MOS transistors NM and three resistors R connected to gates of the MOS transistors NM. One ends of these resistors R are connected to the gates of the corresponding MOS transistors NM, respectively, and the other ends thereof are connected in common to be connected to the corresponding bit line of the capacitance switching signal.

According to the switch SW of FIG. 7, a voltage applied between conductive electrodes of the switch SW is divided by the three MOS transistors, and thus, the breakdown voltage of the switch SW can be improved.

Although FIG. 7 illustrates the example in which the single switch SW is constituted by the three MOS transistors NM, the number of MOS transistors NM that are cascode-connected is not particularly limited. For example, when the single switch SW is constituted by the three MOS transistors NM, each switch SW has an off-capacitance of a power of two with an off-capacitance including a set of the three MOS transistors NM as a reference.

As described above, in the variable capacitance circuit 1 according to the embodiment in which the plurality of series circuits are connected in parallel, the plurality of switches in the plurality of series circuits have different off-capacitances of the powers of two times the reference capacitance, and the plurality of capacitors in the plurality of series circuits have different capacitances of the powers of two times the reference capacitance. Thus, even if the MOS transistor constituting the switch has the off-capacitance, the capacitance value of the variable capacitance circuit 1 can be linearly changed in accordance with the capacitance switching signal.

Since the capacitance value of the variable capacitance circuit 1 can be accurately and linearly switched by the capacitance switching signal according to the embodiment, the embodiment can be applied to, for example, a high-frequency switch for communication whose frequency can be switched. In the high-frequency switch, a phase changes when the frequency is switched, and thus, it is necessary to adjust a capacitance of a capacitor in accordance with the frequency in order to adjust the phase, which requires the variable capacitance circuit 1 that can switch the capacitance linearly as in the embodiment. Since the variable capacitance circuit 1 according to the embodiment can be formed on a silicon on insulator (SOI) substrate similarly to the high-frequency switch, it is also possible to form the variable capacitance circuit 1 in the same chip with the high-frequency switch.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A variable capacitance circuit comprising
a plurality of series circuits connected in parallel, wherein the plurality of series circuits comprise:
a plurality of switches having different off-capacitances that are powers of two times a reference capacitance; and
a plurality of capacitors connected in series to the plurality of switches and having different capacitances that are powers of two times a reference capacitance.

2. The variable capacitance circuit according to claim 1, wherein
the plurality of switches are set to be on or off by a capacitance switching signal having a plurality of bits, and
the plurality of series circuits connected in parallel have a capacitance that is linearly switched by the capacitance switching signal.

3. The variable capacitance circuit according to claim 2, wherein
exponents of the powers are natural numbers to linearly switch off-capacitances of the plurality of switches and capacitances of the plurality of capacitors.

4. The variable capacitance circuit according to claim 3, wherein
exponents of the powers are natural numbers that changes by one.

5. The variable capacitance circuit according to claim 1, wherein
among the plurality of series circuits, a series circuit having the switch with a smallest off-capacitance has a capacitor with a smallest capacitance, and a series circuit having a switch with an m-th off-capacitance (m is an integer of two or more) from the smallest capacitance has a capacitor with an m-th capacitance from the smallest capacitance.

6. The variable capacitance circuit according to claim 5, wherein
a capacitance Ceq of the plurality of series circuits connected in parallel is expressed by:
C_{eq}=C₁·Σₖ₌₀^{N-1}2^{k}Aₖ+C_{off1}·Σₖ₌₀^{N-1}2^{k}Bₖ (1)
where C1 is a smallest capacitance in the plurality of switches, Coff1 is a smallest off-capacitance in the plurality of switches, N is a number of the plurality of series circuits, k is a variable that changes by one from zero to N−1, A is a digital value that is one when the k-th switch is turned on or zero when the k-th switch is turned off, and B is a digital value that is one when the kth switch is turned off or is zero when the k-th switch is turned on.

7. The variable capacitance circuit according to claim 1, wherein
each of the plurality of switches has a MOS transistor that is turned on or off by a gate voltage.

8. The variable capacitance circuit according to claim 5, wherein
the plurality of switches in the plurality of series circuits have the MOS transistors with different gate widths that are powers of two times a reference width or different gate lengths that are powers of two times a reference length.

9. The variable capacitance circuit according to claim 8, wherein
the plurality of switches in the plurality of series circuits have the MOS transistors with different gate widths that are powers of two times the reference width and an identical gate length.

10. The variable capacitance circuit according to claim 8, wherein
the plurality of switches in the plurality of series circuits have the MOS transistors with different gate lengths that are powers of two times the reference length and an identical gate width.

11. The variable capacitance circuit according to claim 5, wherein
at least one of the plurality of switches in the plurality of series circuits is configured by parallel connection of a first number of the MOS transistors, the first number being a power of two times a reference number.

12. The variable capacitance circuit according to claim 5, wherein
the plurality of switches in the plurality of series circuits have a plurality of the MOS transistors in cascode-connection and a plurality of resistors having one ends connected to gates of the plurality of MOS transistors, respectively, and
a capacitance switching signal to turn on or off the MOS transistor is input to other ends of the plurality of resistors.

13. The variable capacitance circuit according to claim 11, wherein
at least one of the plurality of switches in the plurality of series circuits comprises the reference number of the MOS transistors.

14. The variable capacitance circuit according to claim 13, wherein
at least one of the plurality of switches in the plurality of series circuits is configured by parallel connection of a second number of the MOS transistors, the second number being twice the first number.
